(19) United States
(12) Patent Application Publication
(10) Pub. No.: US 2002/0001177 A1
(43) Pub. Date: Jan. 3, 2002

(54) Power module having electronic power components, and a method of manufacturing such a module

(75) Inventor: Alain Petitbon, Pau (FR)

Correspondence Address: SUGHRUE, MION, ZINN, MACPEAK & SEAS, PLLC, 2100 Pennsylvania Avenue, NW, Washington, DC, 20037-3213, US

(73) Assignee: ALSTOM

(21) Appl. No.: 09/879,130

(22) Filed: Jun. 13, 2001

(30) Foreign Application Priority Data
Jun. 23, 2000 (FR) 00 08 121

(51) Int. Cl. H05K 7/20

(52) U.S. Cl. 361/690; 315/82

(57) ABSTRACT

power module having electronic power components, the module comprising a soleplate constituting a heat exchanger for dumping the power dissipated by the Joule effect in said power components, wherein said soleplate has a face that is provided with a skin of aluminum alloy, said skin being covered in an insulating layer of aluminum oxide obtained by anodizing said skin, said insulating layer constituting a substrate on which metallized tracks are made in order to receive said electronic components, the other face of said soleplate being in contact with a cooling fluid.

The invention relates to a power module having electronic power components, and to a method of manufacturing such a power module. More particularly, the invention relates to a power module comprising a soleplate constituting a heat exchanger for dumping the power dissipated by the Joule effect in the power components.

An application of the present invention lies in manufacturing inverters in the medium power range, in particular for highway applications of the electric vehicle type in which power requirements are of the order of 30 kilowatts (kW) to 200 kW, and voltages across the terminals of the power modules are of the order of 500 volts (V) to 2000 V.

### BACKGROUND OF THE INVENTION

It is known to make a power module built up of power components brazed on an aluminum skin placed on one face of a ceramic substrate made of aluminum nitride AlN, the other face of the AlN ceramic substrate being covered in an aluminum skin and stuck to an AlSiC composite soleplate constituting a heat exchanger. In such a power module, the AlN substrate provides electrical insulation for the high voltage components relative to the AlSiC soleplate which is grounded, however such an AlN aluminum nitride substrate is relatively expensive and is commercially available with a minimum thickness of at least 0.635 millimeters (mm) whereas in some applications, and in particular for withstanding voltages in electric vehicles, a thickness of 0.1 mm would suffice to provide insulation. These drawbacks together lead to power modules being too expensive for automotive applications.

### OBJECT AND SUMMARY OF THE INVENTION

The object of the present invention is thus to propose a power module which provides good heat dissipation of the power given off by the power components and which is simple and of low cost to manufacture.

The invention provides a power module having electronic power components, the module comprising a soleplate constituting a heat exchanger for dumping the power dissipated by the Joule effect in said power components, wherein said soleplate has a face that is provided with a skin of aluminum alloy, said skin being covered in an insulating layer of aluminum oxide obtained by anodizing said skin, said insulating layer constituting a substrate on which metallized tracks are made in order to receive said electronic components, the other face of said soleplate being in contact with a cooling fluid.

In particular embodiments, the power module can have one or more of the following characteristics taken individually or in any technically feasible combination:

the soleplate is made of AlSiC composite;

the soleplate is made of aluminum;

the face of the soleplate which comes into contact with the cooling fluid has studs or microchannels that dip into the fluid, the studs or microchannels being made directly on the soleplate or on an aluminum skin applied to the soleplate;

the metallized tracks are made by depositing copper;

the power components are brazed to the copper tracks;

the power components are IGBT components; and

three groups of IGBT components are brazed onto a common substrate, the tracks of each group of IGBT components being separated from one another so that two substrates can constitute a three-phase inverter.

The invention also provides a method of manufacturing a power module as described above, wherein said aluminum oxide layer is obtained by anodizing the aluminum alloy skin in sulfuric acid at about 0° C.

In various implementations, the method of manufacture can comprise one or more of the following characteristics taken individually or in any technically feasible combination:

the layer obtained in this way is immersed in hot water to form aluminum hydroxide on its surface so as to reduce the porosity of the aluminum oxide layer;

the aluminum alloy skin covering the soleplate is obtained directly when molding the soleplate by means of a mold of appropriate shape; and

the aluminum oxide layer is metallized by electrolytically depositing copper on tracks that have previously been activated by ultraviolet laser treatment, the copper tracks subsequently being nickel-plated by the electroless process.

### BRIEF DESCRIPTION OF THE DRAWINGS

The objects, features, and advantages of the present invention will be better understood on reading the following detailed description of various embodiments given as non-limiting examples and with reference to the accompanying drawings, in which:

FIG. 1 is a diagrammatic section view of a power module constituting a first embodiment of the invention and mounted on a water manifold;

FIG. 2 is a view of the FIG. 1 power module from below;

FIG. 3 is a view of the FIG. 1 power module from above; and

FIG. 4 is a diagrammatic section view of a power module constituting a second embodiment of the invention.

### MORE DETAILED DESCRIPTION

To make the drawings easier to read, only those elements which are necessary for understanding the invention are shown.

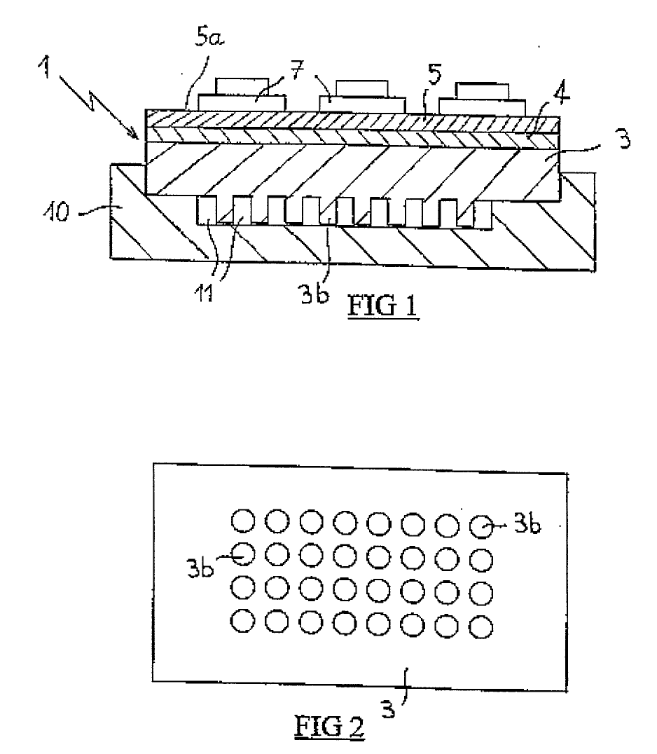

FIG. 1 shows a power module 1 associated with a water manifold 10 made of molded plastics and having a section 11 in which cooling water flows.

The power module 1 comprises a soleplate 3 of aluminum silicon carbide (AlSiC) composite fixed in leakproof manner on the water manifold 10 and having a bottom face fitted with studs 3b (shown in FIG. 2) that dip into the fluid flow section 11 of the manifold 10 so as to enhance heat exchange between the AlSiC soleplate 3 and the cooling fluid.

The top face of the AlSiC soleplate 3 has a skin 4 of aluminum alloy which is covered in a layer 5 of aluminum oxide that is 50 micrometers (μm) to 100 μm thick and that provides electrical insulation capable of withstanding voltage differences of more than 1000 V between the two faces of the aluminum oxide layer, without the insulation breaking down.

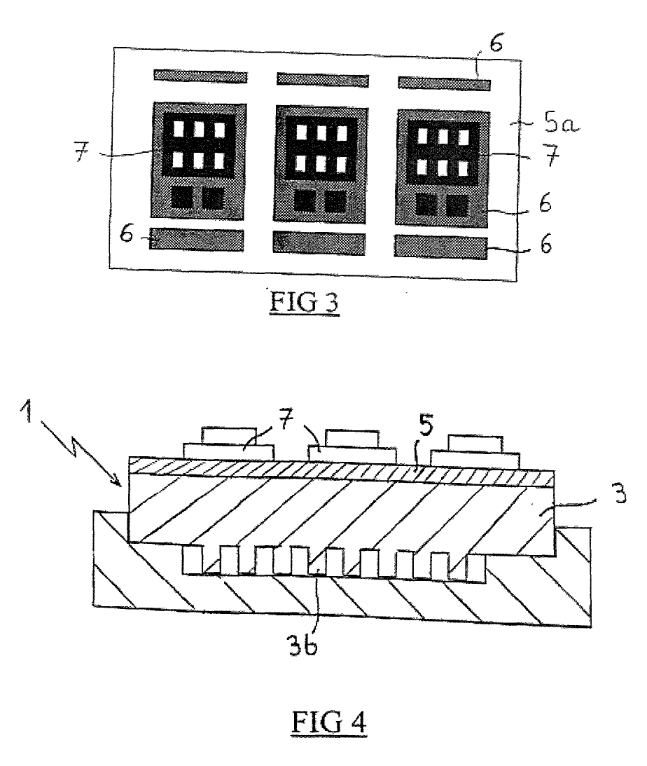

The soleplate 3 provided with its layer 5 of aluminum oxide constitutes a substrate on which tracks 6 are metallized in a pattern that is predetermined to serve as a current collector for three groups of insulated gate bipolar transistors (IGBTs) 7 that are brazed to said metallized tracks 6. Advantageously, and as shown in FIG. 3, the tracks 6 for feeding each of the three IGBTs are separated from one another so as to enable half of a three-phase inverter to be implemented on a single substrate.

The method of manufacturing such a power module is described below.

The AlSiC soleplate 3 is made in conventional manner by injecting aluminum into a mold onto silicon carbide fibers, the shape of the mold being suitable to ensure that the aluminum skin 4 forms on the top surface of the AlSiC soleplate. In a variant (not shown), the bottom face of the soleplate 3 which comes into contact with the cooling fluid could equally well be given an aluminum skin, presenting studs or microchannels, made directly during the operation of molding the soleplate 3 by having a mold of suitable shape.

The aluminum alloy skin 4 of the soleplate 3 is then covered in a layer 5 of aluminum oxide by anodizing the skin 4 in sulfuric acid. At ambient temperature, such anodization makes it possible to obtain aluminum oxide having a thickness of about 20 μm, the thickness of the aluminum oxide being limited by the oxide that is formed dissolving in the acid. Anodization is preferably performed at a temperature of 0° C. so as to obtain a greater thickness of aluminum oxide, up to 100 μm, with the oxide deposit obtained in this way being immersed in hot water in order to diminish the porosity of the aluminum oxide layer 5 by forming aluminum hydroxide.

Naturally, the thickness of the aluminum oxide layer 5 formed in this way also depends on the aluminum content of the alloy used to constitute the skin 4 since the richer the alloy is in aluminum the greater the thickness of the aluminum layer 5 that is created by anodization.

The top face 5a of the aluminum oxide layer 5 is then metallized by electrolytically depositing copper on the tracks 6 that have previously been activated by UV laser treatment and then nickel-plated using the “electroless” process, the adhesion of the metal layers being reinforced by annealing at 400° C. to 500° C. which is tolerable for aluminum and its alloys. A similar metallization method is described in French patent application FR-A1-2 681 078. The IGBT components 7 are subsequently brazed in conventional manner onto the copper tracks 6.

This method of manufacture makes it possible to obtain very good heat conduction between the aluminum oxide layer 5 and the skin 4 by the layer 5 interpenetrating into the skin 4. Furthermore, since the skin 4 is obtained directly while molding the AlSiC soleplate 3, it is integral with the soleplate 3 without any separation interface thus ensuring excellent thermal conductivity between the skin 4 and the soleplate 3.

Consequently this method of manufacture makes it possible to obtain a low cost power module that provides good cooling of the power components because of the very good thermal conductivity between the various layers of the power module. Furthermore, the substrate obtained in this way presents very little differential thermal expansion between its layers and is therefore very reliable, presenting very little risk of the brazing delaminating after some large number of thermal cycles. This method of manufacture also makes it possible to match the thickness of the aluminum oxide layer constituting the electrical insulation to the requirements of the power module so as to minimize the thickness of the oxide layer, thereby reducing its thermal resistance.

FIG. 4 shows a second embodiment of a power module of the invention which differs from the above-described first embodiment by the fact that the soleplate 3 is made entirely out of aluminum alloy. In FIG. 4, the power module 1 comprises a soleplate 3 made of aluminum and having a bottom face which comes into contact with the cooling fluid that is provided with studs 3b that are obtained directly while molding the aluminum soleplate 3. The top face of the soleplate 3 is covered in a layer 5 of aluminum oxide obtained by anodization using a method similar to that described for the first embodiment of the invention. Tracks are then metallized on the aluminum oxide layer 5 using a method similar to that described for the first embodiment so as to act as a current collector for three groups of IGBT components 7, which components are brazed to the tracks by means of a soft tin, lead, or silver type solder that is capable of accommodating differential expansion.

Such a variant embodiment of the invention serves to further reduce the cost of manufacturing the power module by eliminating the use of the AlSiC composite, replacing it with aluminum alloy. Nevertheless, the power module obtained in this way is less reliable in the face of thermal cycling because of the greater differential expansion between the power components and the aluminum soleplate, and it therefore requires a soft solder to be used for brazing the components.

1. A power module having electronic power components, the module comprising a soleplate constituting a heat exchanger for dumping the power dissipated by the Joule effect in said power components, wherein said soleplate has a face that is provided with a skin of aluminum alloy, said skin being covered in an insulating layer of aluminum oxide obtained by anodizing said skin, said insulating layer constituting a substrate on which metallized tracks are made in order to receive said electronic components, the other face of said soleplate being in contact with a cooling fluid.

2. A power module according to claim 1, wherein said soleplate is made of AlSiC composite.

3. A power module according to claim 1, wherein said soleplate is made of aluminum.

4. A power module according to claim 1, wherein the face of the soleplate which comes into contact with the cooling fluid has studs or microchannels that dip into said fluid, said studs or microchannels being made directly on the soleplate or on an aluminum skin applied to said soleplate.

5. A power module according to claim 1, wherein the metallized tracks are made by depositing copper.

6. A power module according to claim 5, wherein said power components are brazed to said copper tracks.

7. A power module according to claim 1, wherein said power components are IGBT components.

8. A power module according to claim 7, wherein three groups of IGBT components are brazed onto a common substrate, the tracks of each group of IGBT components being separated from one another so that two substrates can constitute a three-phase inverter.

9. A method of manufacturing a power module according to claim 1, wherein said aluminum oxide layer is obtained by anodizing the aluminum alloy skin in sulfuric acid at about 0° C.

10. A method of manufacture according to claim 9, wherein the layer obtained in this way is immersed in hot water to form aluminum hydroxide on its surface so as to reduce the porosity of said aluminum oxide layer.

11. A method of manufacture according to claim 9, wherein the aluminum alloy skin covering the soleplate is obtained directly when molding said soleplate by means of a mold of appropriate shape.

12. A method of manufacture according to claim 9, wherein the aluminum oxide layer is metallized by electrolytically depositing copper on tracks that have previously been activated by ultraviolet laser treatment, said copper tracks subsequently being nickel-plated by the electroless process.
